(19) United States
(12) Patent Application Publication
(10) Pub. No.: US 2024/0327136 A1
(43) Pub. Date: Oct. 3, 2024

(54) APPARATUS FOR TRANSFERRING CARRIERS

(71) Applicant: SAMSUNG ELECTRONICS CO., LTD., Suwon-si (KR)

(72) Inventors: Minkyun LEE, Suwon-si (KR); Seunggyu Kang, Suwon-si (KR); Hyunjae Kang, Suwon-si (KR); Sangmin Kim, Suwon-si (KR); Youngwook Kim, Suwon-si (KR); Jaesung Byun, Suwon-si (KR); Yongjun Ahn, Suwon-si (KR); Yongjun Ahn, Suwon-si (KR); Hyunwoo Lee, Suwon-si (KR); Jeonghun Lim, Suwon-si (KR); Junhyuk Chang, Suwon-si (KR)

(73) Assignee: SAMSUNG ELECTRONICS CO., LTD., Suwon-si (KR)

(21) Appl. No.: 18/383,656

(22) Filed: Oct. 25, 2023

(30) Foreign Application Priority Data
Mar. 28, 2023 (KR) 10-2023-0040170

(51) Int. Cl. B65G 47/90; H01L 21/677; H01L 21/687

(52) U.S. Cl. CPC B65G 47/90; H01L 21/67712; H01L 21/67769; H01L 21/68707

(57) ABSTRACT

An apparatus includes an elevator, a plurality of storages, a plurality of first robots and a plurality of second robots. The elevator may elevate a vehicle containing a plurality of semiconductor device carriers to position the vehicle at each of a plurality of process floors. At least one of the plurality of storages may be provided at each of the plurality of process floors to store the plurality of semiconductor device carriers. At least one of the plurality of first robots may be provided at each of the plurality of process floors to transfer the vehicle between the elevator and a respective one of the plurality of process floors. At least one of the second robots may be provided at each of the plurality of process floors to transfer at least one of the plurality of semiconductor device carriers between the vehicle and one of the plurality of storages.

### CROSS-REFERENCE TO RELATED APPLICATION

This application claims priority under 35 U.S.C. § 119 to Korean Patent Application No. 10-2023-0040170, filed on Mar. 28, 2023 in the Korean Intellectual Property Office (KIPO), the disclosure of which is incorporated by reference herein in its entirety.

### BACKGROUND

### 1. Field

Example embodiments of the present disclosure relate to an apparatus for transferring carriers, and more particularly, to an apparatus for vertically transferring carriers configured to receive a semiconductor fabrication part.

### 2. Description of Related Art

A carrier may receive a semiconductor fabrication part. The carrier may be loaded into a vehicle. The vehicle may be transferred to various semiconductor fabrication processes. Particularly, the vehicle with the carrier may be vertically transferred to a plurality of process floors where the semiconductor fabrication processes may be performed.

To improve a productivity of a semiconductor device fabrication process, it may be advantageous to rapidly transfer a plurality of the carriers to the process floors. However, a transferring apparatus may transfer only two carriers, so a bottleneck may be frequently generated in transferring the carriers. Thus, a time for transferring the carriers may be increased and the productivity of the semiconductor device fabrication process may be reduced.

### SUMMARY

One or more example embodiments provide an apparatus for rapidly transferring a plurality of carriers to process floors.

According to an aspect of an example embodiment, an apparatus includes: an elevator configured to elevate a vehicle containing a plurality of semiconductor device carriers to position the vehicle at each of a plurality of process floors: a plurality of storages, wherein at least one of the plurality of storages is provided at each of the plurality of process floors, and each of the plurality of storages is configured to store at least one of the plurality of semiconductor device carriers: a plurality of first robots, wherein at least one of the plurality of first robots is provided at each of the plurality of process floors, and each of the plurality of first robots is configured to transfer the vehicle between the elevator and a respective one of the plurality of process floors: and a plurality of second robots, wherein at least one of the plurality of second robots is provided at each of the plurality of process floors, and each of the plurality of second robots is configured to transfer at least one of the plurality of semiconductor device carriers between the vehicle and one of the plurality of storages.

According to an aspect of an example embodiment, an apparatus includes: an elevator configured to elevate a vehicle containing a plurality of semiconductor device carriers to position the vehicle at each of a plurality of process floors: a plurality of storages, wherein at least one of the plurality of storages is provided at each of the plurality of process floors, and each of the plurality of storages includes a plurality of shelves configured to store the plurality of semiconductor device carriers: a plurality of first robots, wherein at least one of the plurality of first robots is provided at each of the plurality of process floors, and each of the plurality of first robots is configured to transfer the vehicle between the elevator and a respective one of the plurality of process floors: a plurality of second robots, wherein a pair of second robots of the plurality of second robots is provided at each of the plurality of process floors, a first one of the pair of second robots is provided at a first side of one of the plurality of first robots, a second one of the pair of second robots is provided at a second side of the one of the plurality of first robots, and each of the plurality of second robots is configured to transfer at least one of the plurality of semiconductor device carriers between the vehicle and one of the plurality of storages: and a controller configured to control operations of the elevator, the plurality of storages, the plurality of first robots, and the plurality of second robots.

According to an aspect of an example embodiment, an apparatus includes: an elevator configured to elevate a vehicle, into which a plurality of semiconductor device carriers are loaded, in a horizontal direction and a vertical direction to position the vehicle at each of a plurality of process floors: a plurality of storages, wherein a pair of storages of the plurality of storages is provided at each of the plurality of process floors, each of the pair of storages includes a plurality of shelves configured to store semiconductor device carriers of the plurality of semiconductor device carriers in the horizontal direction and the vertical direction; a plurality of first robots, wherein at least one of the plurality of first robots is provided at each of the plurality of process floors, and each of the plurality of first robots is configured to transfer the vehicle between the elevator and a respective one of the plurality of process floors: a plurality of second robots, wherein a pair of second robots the plurality of second robots is provided at each of the plurality of process floors between one of the plurality of first robots and one of the plurality of storages, and each of the plurality of second robots is configured to transfer at least one of the plurality of semiconductor device carriers between the vehicle and one of the plurality of storages; and a controller configured to control operations of the elevator, the plurality of storages, the plurality of first robots and the plurality of second robots.

### BRIEF DESCRIPTION OF THE DRAWINGS

The above and other aspects and features will be more apparent from the following detailed description taken in conjunction with the accompanying drawings, in which:

FIG. 1 is a perspective view illustrating an apparatus for transferring carriers in accordance with one or more example embodiments;

FIG. 2 is an enlarged perspective view illustrating the apparatus in FIG. 1 provided to process floors, according to one or more example embodiments;

FIG. 3 is a front view illustrating the apparatus in FIG. 1, according to one or more example embodiments; and

FIGS. 4, 5, 6 and 7 are plan views illustrating an operation of the apparatus in FIG. 1, according to one or more example embodiments.

### DETAILED DESCRIPTION

Hereinafter, example embodiments will be explained in detail with reference to the accompanying drawings. The same reference numerals are used for the same components in the drawings, and duplicate descriptions thereof are omitted.

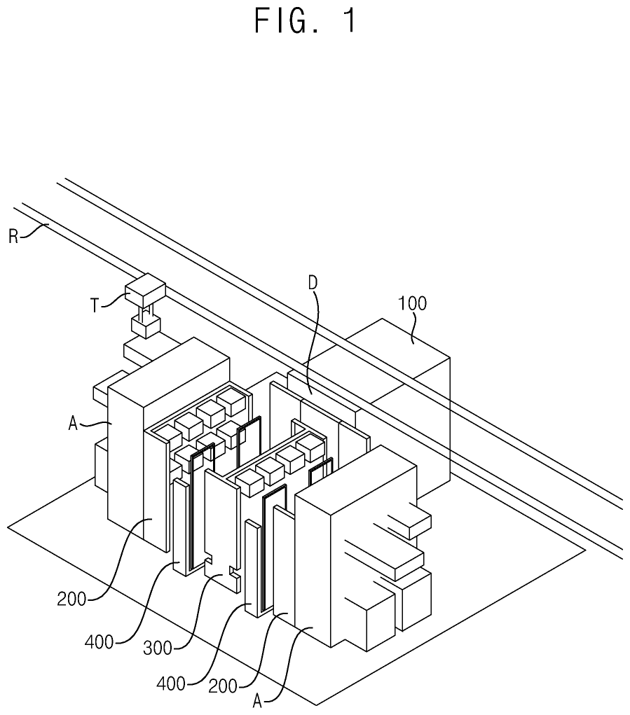

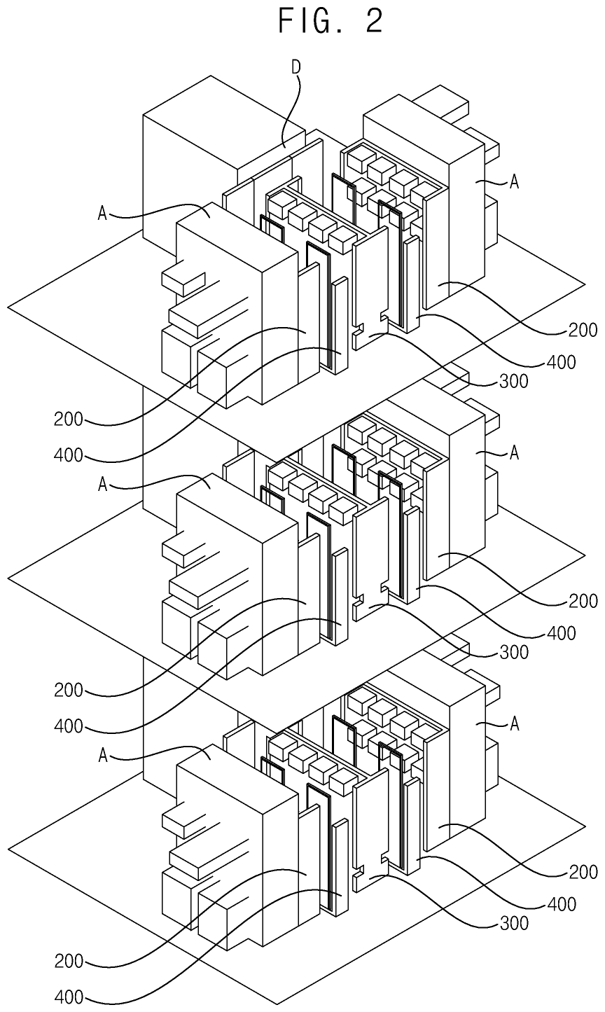

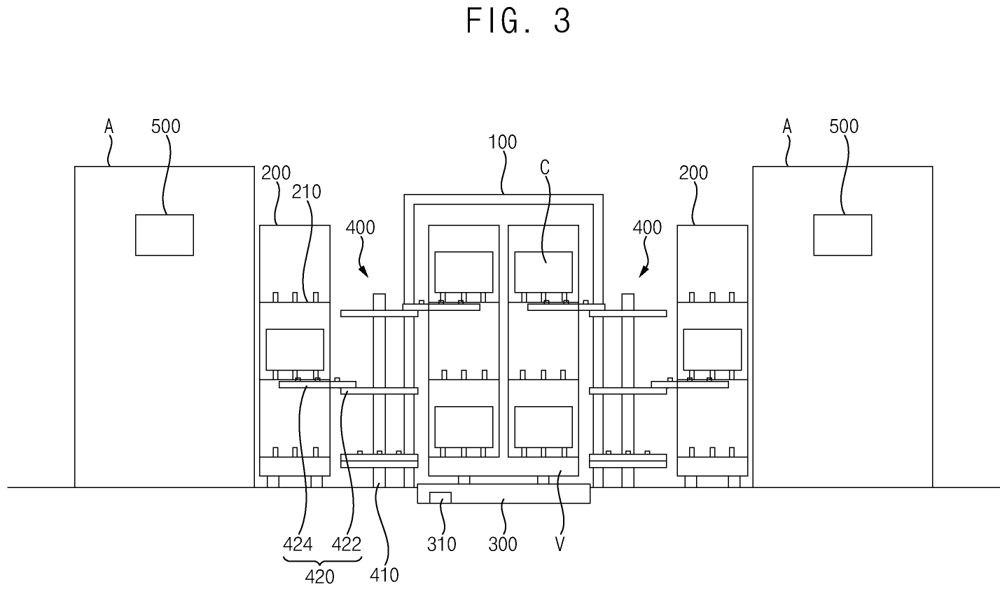

FIG. 1 is a perspective view illustrating an apparatus for transferring carriers in accordance with one or more example embodiments. FIG. 2 is an enlarged perspective view illustrating the apparatus in FIG. 1 provided to process floors according to one or more example embodiments. FIG. 3 is a front view illustrating the apparatus in FIG. 1, according to one or more example embodiments.

An apparatus for transferring carriers in accordance with one or more example embodiments may transfer the carrier C, which is configured to receive a semiconductor part, along a vertical direction. Moreover, according to one or more example embodiments, the apparatus may transfer a plurality of carriers C. The carrier C may include a Front Opening Unified Pod (FOUP), a POD, etc., but one or more example embodiments are not limited thereto. According to one or more example embodiments, semiconductor fabrication processes may be performed on a plurality of process floors in a semiconductor fabrication line. Thus, the carrier C with the semiconductor part may be transferred to the process floors along the vertical direction using the apparatus. A rail R and a transfer vehicle T may be provided on each of the process floors. The transfer vehicle T may be moved along the rail R. The transfer vehicle T may transfer the carrier C, which may be transferred to the process floor, to semiconductor fabrication equipment on the process floor. The operation of the transfer vehicle T may be controlled by an automated material handling system (AMHS), which is referenced in the drawings by the reference character A.

Referring to FIGS. 1, 2 and 3, the apparatus may include an elevator 100, at

least one storage 200, a first robot 300, a second robot 400 and a controller 500.

The elevator 100 may be provided in the semiconductor fabrication line. The elevator 100 may include a door D through which the carrier C may move in and out. The elevator 100 may elevate a vehicle V to the process floors. The carrier C may be loaded into the vehicle V. Thus, the vehicle V may be located at a desired process floor using the elevator 100. Further, a worker may board the elevator 100.

In one or more example embodiments, a plurality of the carriers C may be provided in the vehicle V along a horizontal direction and the vertical direction, but one or more example embodiments are not limited thereto. According to one or more example embodiments, the plurality of carriers C may be provided in the vehicle V along only the horizontal direction or only the vertical direction.

In one or more example embodiments, in order to prevent the semiconductor part, the carrier C and the vehicle V, from being contaminated, the elevator 100 may include a clean elevator having a structure configured to exhaust a contaminant.

The storage 200 may be provided at each of the process floors adjacent to the elevator 100 to store the carrier C. According to one or more example embodiments, the storage 200 may be adjacent to the door D of the elevator 100. Further, the storage 200 may include a pair of storages 200 provided at both sides of the door D of the elevator 100, but one or more example embodiments are not limited thereto. In this case, according to one or more example embodiments, the storages 200 may be provided in a direction substantially perpendicular to the door D of the elevator 100. Thus, an empty space may be provided at the process floor between the door D of the elevator 100 and the storages 200.

In one or more example embodiments, the storage 200 may include a plurality of shelves 210. The shelves 210 may be provided in the vertical direction. The shelves 210 may be spaced apart from each other by a uniform gap. The carrier C may be placed on upper surfaces of the shelves 210. Thus, the gap between the shelves 210 may be greater than a height of the carrier C.

The first robot 300 may be positioned on each of the process floors. According to one or more example embodiments, the first robot 300 may be positioned between the door D of the elevator 100 and the storages 200. The first robot 300 may transfer the vehicle V between the elevator 100 and the process floor. In one or more example embodiments, the first robot 300 may include an automatic driving robot such as a 2-axis articulated robot, but one or more example embodiments are not limited thereto.

According to one or more example embodiments, the first robot 300 may be moved on the process floor in the horizontal direction. The first robot 300 may be docked on the vehicle V. Further, the first robot 300 may transfer the vehicle V from the elevator 100 to the process floor. The first robot 300 may also transfer the vehicle V from the process floor to the elevator 100. According to one or more example embodiments, the first robot 300 may be docked on the vehicle V using a docking structure such as a coupler, a gripper, etc., but one or more example embodiments are not limited thereto. Additionally, a guide rail for guiding the horizontal movement of the first robot 300 may be provided on the process floor.

When a step is provided between the elevator 100 and the process floor, an impact may be applied to the vehicle V when loading the vehicle V into the elevator 100, or when unloading the vehicle V from the elevator 100. The impact may damage the semiconductor part in the carrier C.

In order to prevent damage of the semiconductor part, the first robot 300 may include a sensor 310. The sensor 310 may detect a bottom surface of the elevator 100. According to one or more example embodiments, the sensor 310 may detect whether the bottom surface of the elevator 100 is coplanar with the process floor or not. When the bottom surface of the elevator 100 detected by the sensor 310 is different from the process floor, a signal detected by the sensor 310 may be transmitted to the controller 500.

Additionally, according to one or more example embodiments, a damper may be provided for the vehicle V. The damper may resiliently support the carrier C along the vertical direction to absorb impact applied to the carrier C. The damper may include a resilient material such as a spring, but one or more example embodiments are not limited thereto.

The second robot 400 may be positioned at each of the process floors. The second robot 400 may transfer the carrier C between the vehicle V and the storage 200. That is, the second robot 400 may transfer the carrier C from the vehicle V to the storage 200 or from the storage 200 to the vehicle V.

In one or more example embodiments, when the pair of the storages 200 are provided at the both sides of the door D of the elevator 100, the second robot 400 may comprise a pair of the second robots 400 provided between the first robot 300 and the storages 200. According to one or more example embodiments, when the storage 200 is a single storage 200, a single second robot 400 may be provided between the first robot 300 and the single storage 200.

In one or more example embodiments, the second robot 400 may include a polyaxial joint robot. The second robot 400 may include a transfer shaft 410 and at least one fork 420. The transfer shaft 410 may be rotatably connected to the process floor about a vertical axis. The transfer shaft 410 may receive a rotary force from an actuator.

The fork 420 may be connected to the transfer shaft 410. The fork 420 may transfer the carrier C. That is, the fork 420 may transfer the carrier C from the vehicle V to the storage 200, or the fork 420 may transfer the carrier C from the storage 200 to the vehicle V by rotating the transfer shaft 410.

In one or more example embodiments, the fork 420 may include a first fork 422 and a second fork 424. The first fork 422 may be fixed to the transfer shaft 410. According to one or more example embodiments, the transfer shaft 410 may be inserted into a central portion of the first fork 422. Thus, the first fork 422 may be rotated together with the transfer shaft 410 about the vertical axis. The second fork 424 may be connected to an edge portion of the first fork 422. Thus, the second fork 424 may also be rotated together with the first fork 422. The second fork 424 may support a lower surface of the carrier C. Alternatively, according to one or more example embodiments, the fork 420 may include a single fork or at least three forks.

When a plurality of the carriers C are loaded into the vehicle V along the vertical direction and the shelves 210 are vertically arranged, a plurality of the forks 420 may be vertically spaced apart from each other by a gap. Because the plurality of carriers C may be transferred to the shelves 210 by the respective rotations of the forks 420, each of the forks 420 may have a height corresponding to the height of each of the shelves 210. Further, according to one or more example embodiments, a number of the forks 420 may correspond to a number of the shelves 210.

Alternatively, according to one or more example embodiments, when a height control function is provided to the transfer shaft 410, the height of the fork 420 may not correspond to the height of the shelf 210. According to one or more example embodiments, the number of the forks 420 may not correspond to the numbers of the shelves 210.

The controller 500 may be provided in the AMHS, which is referenced in the drawings by the reference character A. The controller 500 may control the operations of the elevator 100, the storage 200, the first robot 300 and the second robot 400. According to one or more example embodiments, the controller 500 may store information of a corresponding process floor among the process floors to which the carrier C may be transferred. The controller 500 may control positioning the elevator at the corresponding process floor. Further, the controller 500 may check whether the door D of the elevator 100 is opened or closed. The controller 500 may control the operation of the first robot 300, i.e., the docking between the first robot 300 and the vehicle V in accordance with the opening/closing of the door D of the elevator 100.

Further, the controller 500 may receive a signal from the sensor 310 with respect to the bottom surface of the elevator 100. The controller 500 may determine whether the bottom surface of the elevator 100 is coplanar with the corresponding process floor. When the bottom surface of the elevator 100 is not coplanar with the corresponding process floor, the controller 500 may control the elevator 100 to position the bottom surface of the elevator 100 to be coplanar with the corresponding process floor.

The controller 500 may check positions of, from among a plurality of shelves 210, an empty shelf 210 and a shelf 210 on which the carrier C is provided. The controller 500 may control the second robot 400 to transfer the carrier C to the empty shelf 210, or the controller 500 may control the second robot 400 to transfer the carrier C on the shelf 210 to the vehicle V.

According to one or more example embodiments, the controller 500 may independently control the transfer shafts 410 of the second robot 400. That is, the rotation directions of the transfer shafts 410 may be independently controlled by the controller 500. Thus, the forks 420 connected to the transfer shafts 410 may also be independently operated. According to one or more example embodiments, while the fork 420 of one transfer shaft 410 transfers one carrier C from the vehicle V to the empty shelf 210, a fork 420 of another transfer shaft 410 may transfer another carrier C from the shelf 210 to the vehicle V.

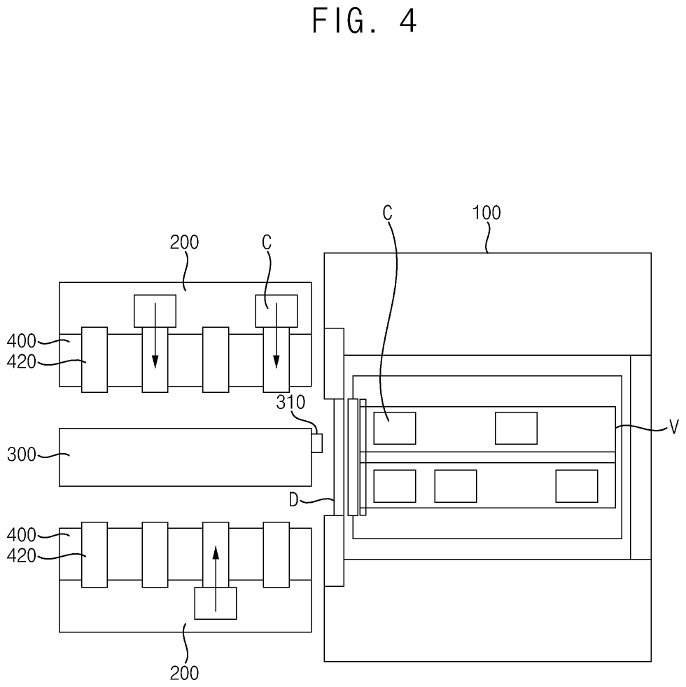

FIGS. 4, 5, 6 and 7 are plan views illustrating an operation of the apparatus in FIG. 1, according to one or more example embodiments.

Referring to FIG. 4, the information of the corresponding process floor to which the carrier C may be transferred may be inputted into the controller 500. The controller 500 may control the elevator 100 to position the elevator 100 at the corresponding process floor. Thus, the vehicle V with the carrier C may be provided at the corresponding process floor by the elevator 100.

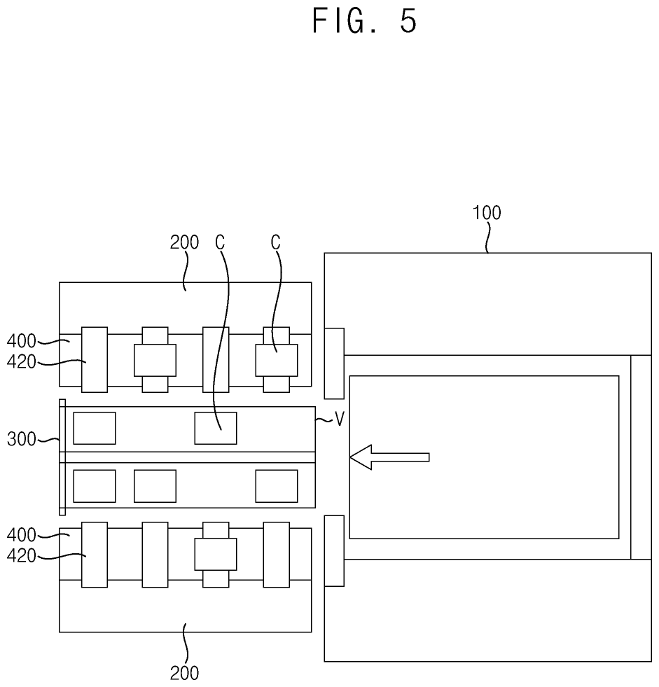

Referring to FIG. 5, the controller 500 may check whether the door D of the elevator 100 is opened or not. When the door D of the elevator 100 is closed, the controller 500 may control the elevator 100 to open the door D of the elevator 100.

Further, the controller 500 may receive the signal from the sensor 310 with respect to the bottom surface of the elevator 100. The controller 500 may determine whether the bottom surface of the elevator 100 is coplanar with the corresponding process floor. When the bottom surface of the elevator 100 is different from the corresponding process floor, the controller 500 may control the elevator 100 to position the bottom surface of the elevator 100 to be coplanar with the corresponding process floor.

The first robot 300 may be moved toward the elevator 100 so that the first robot 300 may be docked on the vehicle V. Thus, the first robot 300 may be connected to the vehicle V. The first robot 300 may be moved from the elevator 100 to unload the vehicle V from the elevator 100. The unloaded vehicle V may be positioned between the second robots 400.

When a step is provided between the elevator 100 and the corresponding process floor, the damper may absorb the impact applied to the vehicle V.

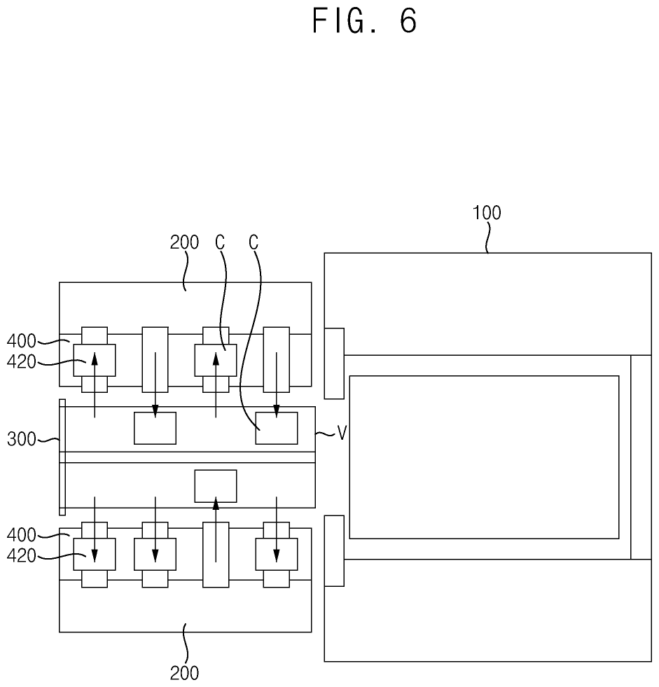

Referring to FIG. 6, the controller 500 may check the positions of the empty shelf 210 and the shelf 210 with the carrier C among the shelves 210. The transfer shaft 410 of the second robot 400 may transfer the carrier C from the vehicle V to the empty shelf 210. Further, the another transfer shaft 410 of the second robot 400 may transfer the carrier C from the shelf 210 to the vehicle V.

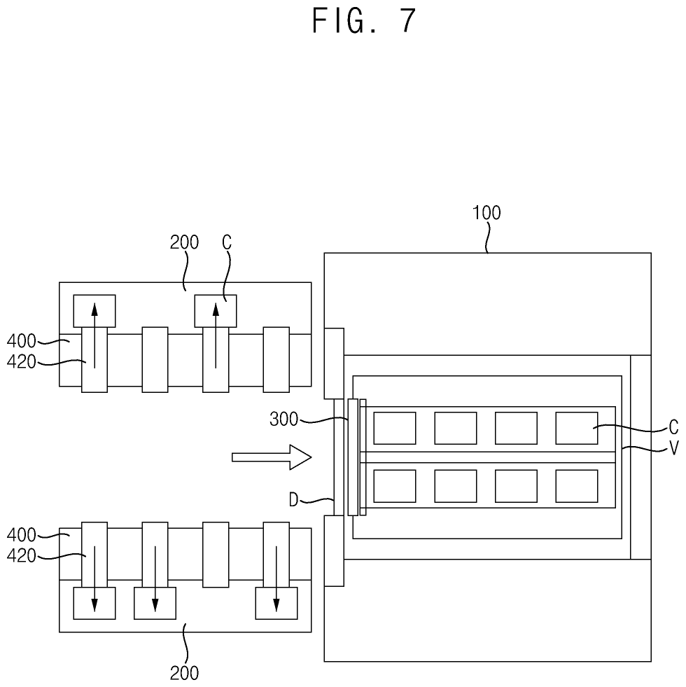

Referring to FIG. 7, when the transfer of the carrier C by the second robot 400 is completed, the first robot 300 may load the vehicle V into the elevator 100.

According to one or more example embodiments, the elevator may rapidly elevate the carrier C to the process floors. Further, the first robot 300 configured to transfer the vehicle V with the carrier C, and the second robot 400 configured to transfer the carrier C, may be provided to each of the process floors so that a time for transferring the carriers may be greatly reduced to improve transfer efficiency. According to one or more example embodiments, the operations of the second robots 400 may be independently performed so that the carriers may be effectively transferred between the vehicle and the storage without any bottleneck. As a result, productivity of a semiconductor device fabrication process may be improved.

The foregoing description of one or more example embodiments is not to be construed as limiting thereof. Although one or more example embodiments have been particularly shown and described, it will be apparent to those skilled in the art that many modifications in form and details may be made to one or more example embodiments without departing from the spirit and scope of the following claims.

What is claimed is:

1. An apparatus comprising:
an elevator configured to elevate a vehicle containing a plurality of semiconductor device carriers to position the vehicle at each of a plurality of process floors;
a plurality of storages, wherein at least one of the plurality of storages is provided at each of the plurality of process floors, and each of the plurality of storages is configured to store at least one of the plurality of semiconductor device carriers;
a plurality of first robots, wherein at least one of the plurality of first robots is provided at each of the plurality of process floors, and each of the plurality of first robots is configured to transfer the vehicle between the elevator and a respective one of the plurality of process floors; and
a plurality of second robots, wherein at least one of the plurality of second robots is provided at each of the plurality of process floors, and each of the plurality of second robots is configured to transfer at least one of the plurality of semiconductor device carriers between the vehicle and one of the plurality of storages.

2. The apparatus of claim 1, wherein the plurality of semiconductor device carriers are loaded into the vehicle in at least one of a horizontal direction or a vertical direction.

3. The apparatus of claim 2, wherein each of the plurality of storages comprises a plurality of shelves configured to store the plurality of semiconductor device carriers in at least one of the horizontal direction or the vertical direction.

4. The apparatus of claim 1, wherein each of the plurality of first robots comprises a sensor configured to detect a bottom surface of the elevator.

5. The apparatus of claim 1, wherein each of the plurality of second robots comprises:
a transfer shaft configured to rotate about a vertical axis; and
at least one fork connected to the transfer shaft and configured to transfer at least one of the plurality of semiconductor device carriers between the vehicle and one of the plurality of storages.

6. The apparatus of claim 5, wherein the transfer shaft comprises a plurality of shafts provided in a horizontal direction.

7. The apparatus of claim 5, wherein the at least one fork comprises a plurality of forks separated by a gap in a vertical direction.

8. The apparatus of claim 1, wherein a first one of the plurality of second robots is provided at a first side of one of the plurality of first robots,
wherein a second one of the plurality of second robots is provided at a second side of the one of the plurality of first robots, and
wherein a pair of storages of the plurality of storages are adjacent to the first one of the plurality of second robots and the second one of the plurality of second robots.

9. The apparatus of claim 1, further comprising a controller configured to control operations of the elevator, the plurality of storages, the plurality of first robots and the plurality of second robots.

10. An apparatus comprising:
an elevator configured to elevate a vehicle containing a plurality of semiconductor device carriers to position the vehicle at each of a plurality of process floors;
a plurality of storages, wherein at least one of the plurality of storages is provided at each of the plurality of process floors, and each of the plurality of storages comprises a plurality of shelves configured to store the plurality of semiconductor device carriers;
a plurality of first robots, wherein at least one of the plurality of first robots is provided at each of the plurality of process floors, and each of the plurality of first robots is configured to transfer the vehicle between the elevator and a respective one of the plurality of process floors;
a plurality of second robots, wherein a pair of second robots of the plurality of second robots is provided at each of the plurality of process floors, a first one of the pair of second robots is provided at a first side of one of the plurality of first robots, a second one of the pair of second robots is provided at a second side of the one of the plurality of first robots, and each of the plurality of second robots is configured to transfer at least one of the plurality of semiconductor device carriers between the vehicle and one of the plurality of storages; and
a controller configured to control operations of the elevator, the plurality of storages, the plurality of first robots, and the plurality of second robots.

11. The apparatus of claim 10, wherein the plurality of semiconductor device carriers are loaded into the vehicle in at least one of a horizontal direction or a vertical direction, and
wherein the plurality of shelves are configured to store the plurality of semiconductor device carriers in at least one of the horizontal direction or the vertical direction.

12. The apparatus of claim 10, wherein each of the plurality of first robots comprises a sensor configured to detect a bottom surface of the elevator.

13. The apparatus of claim 10, wherein each of the plurality of second robots comprises:
a transfer shaft configured to rotate about a vertical axis; and
a plurality of forks connected to the transfer shaft and configured to transfer at least one of the plurality of semiconductor device carriers between the vehicle and one of the plurality of storages.

14. The apparatus of claim 13, wherein the transfer shaft comprises a plurality of shafts provided in a horizontal direction.

15. The apparatus of claim 14, wherein the controller is configured to independently control operations of the transfer shafts.

16. The apparatus of claim 13, wherein the plurality of forks are separated by a gap in a vertical direction.

17. The apparatus of claim 10, further comprising a pair of storages of the plurality of storages provided adjacent to one of the plurality of second robots.

18. An apparatus comprising:
an elevator configured to elevate a vehicle, into which a plurality of semiconductor device carriers are loaded, in a horizontal direction and a vertical direction to position the vehicle at each of a plurality of process floors;
a plurality of storages, wherein a pair of storages of the plurality of storages is provided at each of the plurality of process floors, each of the pair of storages comprises a plurality of shelves configured to store semiconductor device carriers of the plurality of semiconductor device carriers in the horizontal direction and the vertical direction;
a plurality of first robots, wherein at least one of the plurality of first robots is provided at each of the plurality of process floors, and each of the plurality of first robots is configured to transfer the vehicle between the elevator and a respective one of the plurality of process floors;
a plurality of second robots, wherein a pair of second robots the plurality of second robots is provided at each of the plurality of process floors between one of the plurality of first robots and one of the plurality of storages, and each of the plurality of second robots is configured to transfer at least one of the plurality of semiconductor device carriers between the vehicle and one of the plurality of storages; and
a controller configured to control operations of the elevator, the plurality of storages, the plurality of first robots and the plurality of second robots.

19. The apparatus of claim 18, wherein each of the plurality of first robots comprises a sensor configured to detect a bottom surface of the elevator.

20. The apparatus of claim 18, wherein each of the plurality of second robots comprises:
a transfer shaft configured to rotate about a vertical axis; and
a plurality of forks connected to the transfer shaft and configured to transfer at least one of the plurality of semiconductor device carriers between the vehicle and one of the plurality of storages.
